(19) United States
(12) Patent Application Publication
(10) Pub. No.: US 2024/0332320 A1
(43) Pub. Date: Oct. 3, 2024

(54) STRETCHABLE DEVICE

(71) Applicant: Japan Display Inc., Tokyo (JP)

(72) Inventors: Hiroumi KINJO, Tokyo (JP); Masatomo HISHINUMA, Tokyo (JP)

(73) Assignee: Japan Display Inc., Tokyo (JP)

(21) Appl. No.: 18/616,264

(22) Filed: Mar. 26, 2024

(30) Foreign Application Priority Data
Mar. 28, 2023 (JP) 2023-051040

(51) Int. Cl. H01L 27/12; G01B 7/16

(52) U.S. Cl. CPC H01L 27/1248; G01B 7/18; H01L 27/1218

(57) ABSTRACT

According to an aspect, a stretchable device includes: an array substrate comprising a resin base member and an array layer stacked on the resin base member. The resin base member includes: a plurality of bodies disposed apart from one another; and a plurality of hinges that couple the bodies. The array layer includes: a plurality of body array portions provided at the bodies; and a plurality of hinge array portions provided at the hinges. A first body array portion serving as at least part of the body array portions is provided with an array electrode. A common electrode is provided at part of the array layer other than the first body array portion. A conductive portion made of conductive resin is provided between the array electrode and the common electrode, the conductive portion being configured to electrically couple the array electrode to the common electrode and including a conductive filler.

### CROSS-REFERENCE TO RELATED APPLICATION

This application claims the benefit of priority from Japanese Patent Application No. 2023-051040 filed on Mar. 28, 2023, the entire contents of which are incorporated herein by reference.

### BACKGROUND

### 1. Technical Field

What is disclosed herein relates to a stretchable device.

### 2. Description of the Related Art

Stretchable devices have excellent elasticity and flexibility. An array substrate of such a stretchable device includes a resin base member to which an array layer is provided. Such a resin base member includes bodies arrayed in a matrix (row-column configuration) and hinges that couple the bodies to each other. As described in Japanese Patent Application Laid-open Publication No. 2021-118273, for example, the hinges have a meandering shape. When a tensile load acts on the stretchable device, the hinges with a meandering shape are stretched.

It has recently been desired to be able to detect tensile and compressive loads acting on a stretchable device. To detect such loads, strain gauges may be provided at the hinges. If the strain gauges are provided at the hinges, however, the hinges are hard to deform, which may possibly compromise the elasticity and flexibility of the stretchable device. For this reason, it is desired to develop a stretchable device that can detect tensile and compressive loads without compromising the elasticity and flexibility.

for the foregoing reasons, there is a need for a stretchable device that can detect tensile and compressive loads without compromising the elasticity and flexibility.

### SUMMARY

According to an aspect, a stretchable device includes: an array substrate comprising a resin base member and an array layer stacked on the resin base member. The resin base member includes: a plurality of bodies disposed apart from one another; and a plurality of hinges that couple the bodies. The array layer includes: a plurality of body array portions provided at the bodies; and a plurality of hinge array portions provided at the hinges. A first body array portion serving as at least part of the body array portions is provided with an array electrode. A common electrode is provided at part of the array layer other than the first body array portion. A conductive portion made of conductive resin is provided between the array electrode and the common electrode, the conductive portion being configured to electrically couple the array electrode to the common electrode and including a conductive filler inside.

### BRIEF DESCRIPTION OF THE DRAWINGS

FIG. 1 is a schematic perspective view of a stretchable device according to an embodiment;

FIG. 2 is a schematic of a section of the stretchable device according to the embodiment, and more specifically a sectional view along line II-II of FIG. 3;

FIG. 3 is a sectional view seen in the direction of arrow along line III-III of FIG. 2;

FIG. 4 is a sectional view seen in the direction of arrow along line IV-IV of FIG. 2;

FIG. 5 is a sectional view seen in the direction of arrow along line V-V of FIG. 4;

FIG. 6 is a sectional view seen in the direction of arrow along line IV-IV of FIG. 2 and is a schematic of an area in which currents flow;

FIG. 7 is a circuit diagram of the circuit configuration of the stretchable device according to a first embodiment;

FIG. 8 is a sectional view of the stretchable device according to a first modification;

FIG. 9 is a sectional view of the stretchable device according to a second embodiment;

FIG. 10 is a plan view of an array substrate of the stretchable device according to the second embodiment viewed from a first resin layer;

FIG. 11 is a sectional view of the stretchable device according to a third embodiment;

FIG. 12 is a schematic of the stretchable device according to the third embodiment on which a bending load acts, as viewed in the planar direction;

FIG. 13 is a sectional view of the stretchable device according to a fourth embodiment;

FIG. 14 is a plan view of the array substrate of the stretchable device according to a fifth embodiment viewed from the first resin layer;

FIG. 15 is a circuit diagram of the circuit configuration according to a second modification;

FIG. 16 is a schematic of an example of the state in detection in the second modification; and

FIG. 17 is a schematic of an example of the state in detection in the second modification.

### DETAILED DESCRIPTION

Exemplary aspects (embodiments) to embody a stretchable device according to the present disclosure are described below in greater detail with reference to the accompanying drawings. The contents described in the embodiments below are not intended to limit the invention according to the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present invention and easily conceivable by those skilled in the art naturally fall within the scope of the present invention. To simplify the explanation, the drawings may possibly illustrate the width, the thickness, the shape, and other elements of each unit more schematically than the actual aspect. These elements, however, are given by way of example only and are not intended to limit interpretation of the present invention. In the present specification and the drawings, components similar to those previously described with reference to previous drawings are denoted by the same reference numerals, and detailed explanation thereof may be appropriately omitted.

When the term “on” is used to describe an aspect where a first structure is disposed on a second structure in the present specification and the claims, it includes both of the following cases unless otherwise noted: a case where the first structure is disposed on and in contact with the second structure, and a case where the first structure is disposed above the second structure with still another structure interposed therebetween.

### First Embodiment

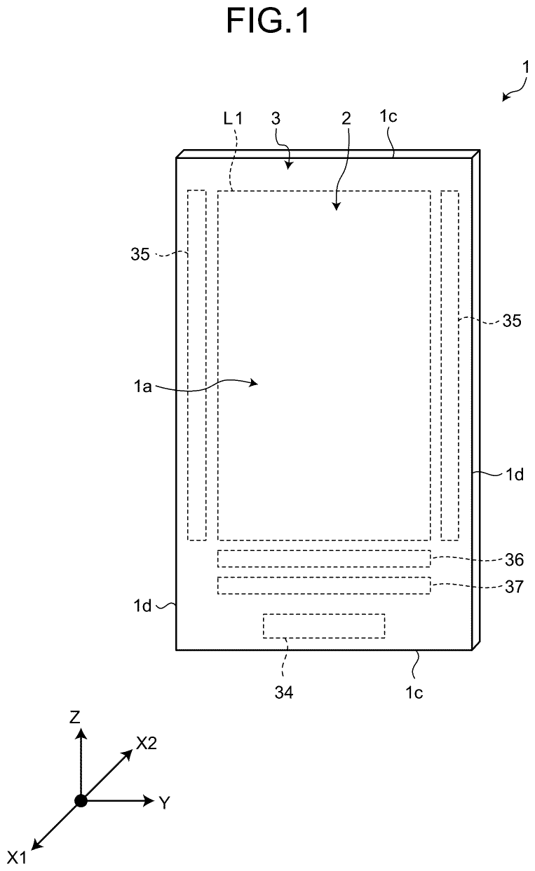

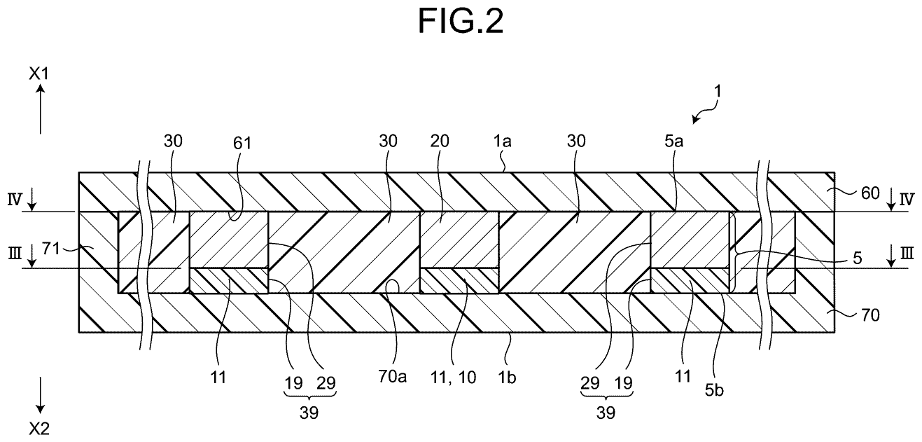

FIG. 1 is a schematic perspective view of a stretchable device according to an embodiment. As illustrated in FIG. 1, this stretchable device 1 has a flat plate shape. The stretchable device 1 has a front surface 1a and a back surface 1b (not illustrated in FIG. 1, and refer to FIG. 2) facing opposite to each other.

In the following description, the direction in which the front surface 1a faces when viewed from the stretchable device 1 is referred to as a first direction X1. The direction in which the back surface 1b faces when viewed from the stretchable device 1 is referred to as a second direction X2. The direction orthogonal to the front surface 1a and the back surface 1b is referred to as a stacking direction. The direction parallel to the front surface 1a and the back surface 1b is referred to as a planar direction. The view of the stretchable device 1 in the first direction X1 may be referred to as plan view.

The stretchable device 1 has a rectangular (quadrilateral) shape in plan view. Therefore, the front surface 1a has a pair of short sides 1c and a pair of long sides 1d. In the following description, a direction parallel to the short side 1c in the planar direction is referred to as a first planar direction Y. A direction parallel to the long side 1d in the planar direction is referred to as a second planar direction Z. The first planar direction Y and the second planar direction Z are orthogonal to each other.

The stretchable device 1 is divided into a detection region 2 and a peripheral region 3. The detection region 2 is a region in which a load applied to the stretchable device 1 can be detected. The peripheral region 3 is a frame-shaped region surrounding the outer periphery of the detection region 2. In FIG. 1, a boundary line L1 is illustrated to make it easier for the boundary between the detection region 2 and the peripheral region 3 to be recognized.

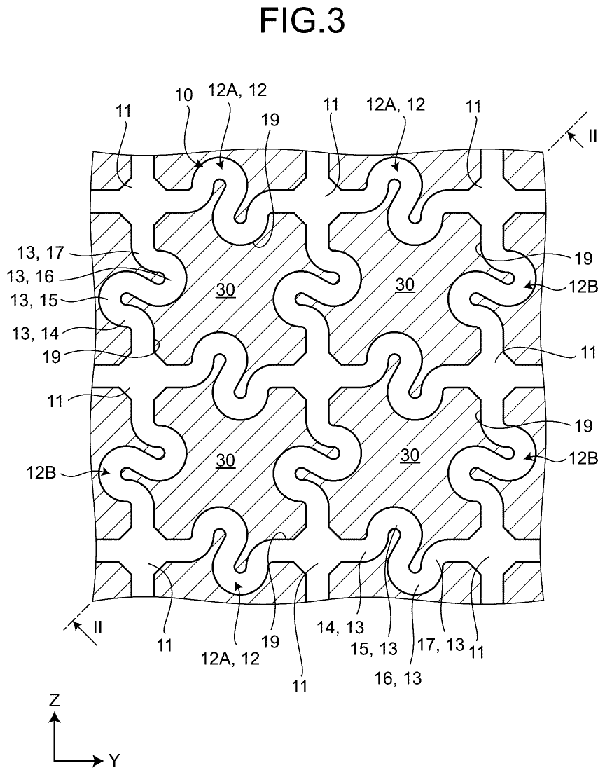

FIG. 2 is a schematic of a section of the stretchable device according to the embodiment, and more specifically a sectional view along line II-II of FIG. 3. As illustrated in FIG. 2, the stretchable device 1 includes a second resin layer 70, an array substrate 5, and a first resin layer 60 stacked in the order as listed, in the stacking direction. Therefore, the first resin layer 60 is stacked on the array substrate 5 in the first direction X1. The second resin layer 70 is stacked on the array substrate 5 in the second direction X2. The array substrate 5 includes a resin base member 10 stacked on the second resin layer 70 in the first direction X1 and an array layer 20 stacked on the resin base member 10 in the first direction X1.

The first resin layer 60 and the second resin layer 70 extend in the planar direction and have a plate shape. The first resin layer 60 is provided on a first surface 5a of the array substrate 5 in the first direction X1. The surface of the first resin layer 60 in the first direction X1 serves as the front surface 1a. The second resin layer 70 is provided on a second surface 5b of the array substrate 5 in the second direction X2. The surface of the second resin layer 70 facing in the second direction X2 serves as the back surface 1b. The surface of the second resin layer 70 in the first direction X1 serves as a stacking surface 70a on which the array substrate 5 is stacked.

The stacking surface 70a of the second resin layer 70 is provided with an annular portion 71 extending along the ends of the stacking surface 70a and protruding in the first direction X1. The annular portion 71 surrounds the outer periphery of the array substrate 5. The surface of the annular portion 71 in the first direction X1 adheres to a surface 61 of the first resin layer 60 in the second direction X2. Therefore, the first resin layer 60 and the second resin layer 70 cooperate to serve as a housing that accommodates the array substrate 5. The second resin layer 70 has insulating, elastic, and flexible properties. While the second resin layer 70 is made of resin, such as polyimide, the resin according to the present disclosure is not limited to polyimide. The resin may be acrylic resin, epoxy resin, urethane resin, or the like and is not particularly limited.

The first resin layer 60 is made of conductive resin. Conductive resin is resin that includes conductive fillers (microparticles) inside. The microparticles are dispersed in the resin. The conductive resin according to the present embodiment is conductive in an undeformed state. When a compressive load acts on the conductive resin, the fillers are in contact with or in proximity to each other, and the resistance of the conductive resin decreases. By contrast, when a tensile load acts on the conductive resin, the fillers are separated from each other, and the resistance of the conductive resin increases. In the first resin layer 60, the resin constituting the conductive resin has elastic and flexible properties.

FIG. 3 is a sectional view seen in the direction of arrow along line III-III of FIG. 2. The resin base member 10 is provided on the stacking surface 70a (refer to FIG. 2) of the second resin layer 70. The resin base member 10 has elastic, flexible, and insulating properties. The resin base member 10 is made of resin material, such as polyimide. The resin base member 10 includes a plurality of bodies 11 and a plurality of hinges 12 meandering and extending in the planar direction. The bodies 11 and the hinges 12 are disposed in the detection region 2 (refer to FIG. 1).

The body 11 has a quadrilateral (square) shape in plan view. The body 11 is disposed with its four corners facing the first planar direction Y and the second planar direction Z. The bodies 11 are arrayed in the first planar direction Y and the second planar direction Z and are separated from one another. The shape of the body 11 according to the present disclosure in plan view is not limited to a quadrilateral shape and may be circular or other polygonal shapes.

The hinge 12 has four bends 13 and extends in the planar direction while meandering. Each bend 13 according to the present embodiment has an arc shape. The bend according to the present disclosure does not necessarily have an arc shape and may have an angular shape. The number of bends is not limited to four.

The four bends 13 are a first arc 14, a second arc 15, a third arc 16, and a fourth arc 17 arranged in this order from one end to the other of the hinge 12. The first arc 14 and the fourth arc 17 each form a quadrant and are bent at 90 degrees. The second arc 15 and the third arc 16 each form a semi-circular arc and are bent at 180 degrees.

When a tensile load acts on the resin base member 10 in the planar direction, the first arc 14, the second arc 15, the third arc 16, and the fourth arc 17 are each deformed such that the curvature decreases. As a result, the length of the hinge 12 from one end to the other increases, and the bodies 11 move away from each other. By contrast, when a compressive load acts on the resin base member 10, the first arc 14, the second arc 15, the third arc 16, and the fourth arc 17 are each deformed such that the curvature increases. As a result, the length of the hinge 12 from one end to the other decreases, and the bodies 11 move closer to each other.

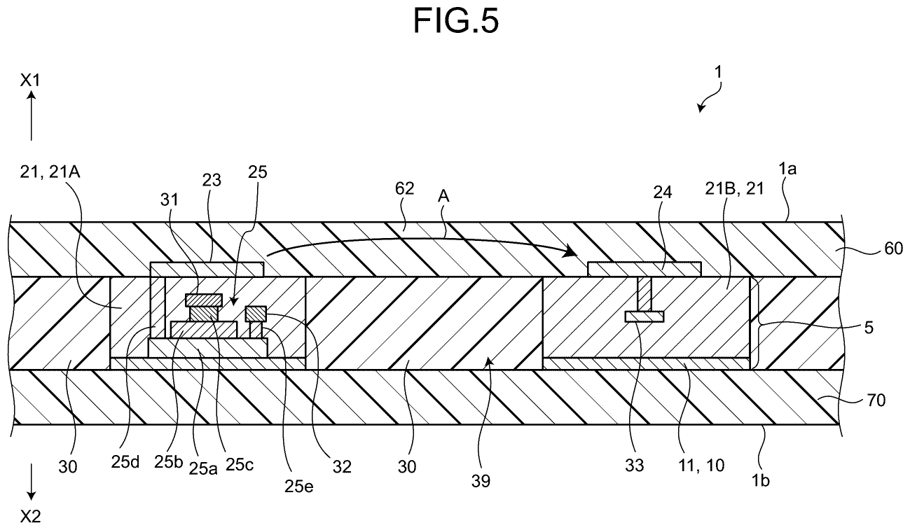

Thus, when a load acts on the resin base member 10, the hinges 12 are deformed, whereby the load acting on the bodies 11 is small. This mechanism suppresses damage to functional elements (transistors 25 (refer to FIG. 5) according to the present embodiment) stacked on the bodies 11. The hinges 12 include a lateral hinge 12A extending in the first planar direction Y and a longitudinal hinge 12B extending in the second planar direction Z.

The resin base member 10 has a plurality of base member through-holes 19 passing through the resin base member 10 in the stacking direction. The base member through-hole 19 is surrounded by four bodies 11 and four hinges 12.

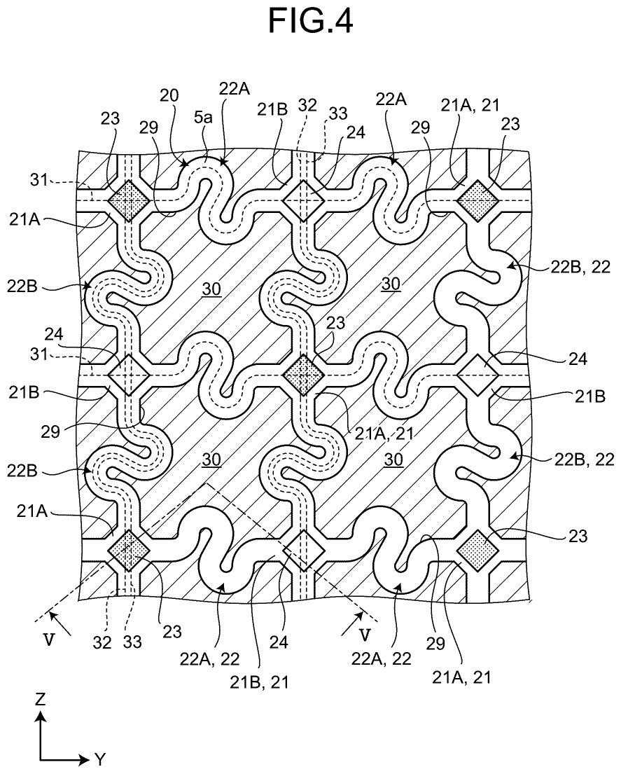

FIG. 4 is a sectional view seen in the direction of arrow along line IV-IV of FIG. 2. The array layer 20 is stacked on the resin base member 10 and has the same shape as that of the resin base member 10 in plan view. Therefore, the array layer 20 includes a plurality of body array portions 21 (also called the body array layers) stacked on the bodies 11 and a plurality of hinge array portions 22 (also called the hinge array layers) stacked on the hinges 12. The array layer 20 has a plurality of array layer through-holes 29 passing through the array layer 20 in the stacking direction.

As illustrated in FIG. 2, the base member through-hole 19 and the array layer through-hole 29 are continuously formed in the stacking direction and constitute a hollow hole 39 passing through the array substrate 5 in the stacking direction. The hollow hole 39 is provided with an intermediate resin portion 30.

The intermediate resin portion 30 has insulating, elastic, and flexible properties. While the intermediate resin portion 30 is made of resin, such as polyimide, the resin according to the present disclosure is not limited to polyimide. The resin may be acrylic resin, epoxy resin, urethane resin, or the like and is not particularly limited.

As illustrated in FIG. 4, the body array portions 21 include a first body array portion 21A and a second body array portion 21B. The first body array portion 21A is provided with an array electrode 23 on the first surface 5a facing the first direction X1. The second body array portion 21B is provided with a common electrode 24 on the first surface 5a. The first body array portions 21A and the second body array portions 21B are alternately arrayed in the first planar direction Y and the second planar direction Z. Therefore, the array electrodes 23 and the common electrodes 24 are also alternately arrayed in the first planar direction Y and the second planar direction Z. In other words, the common electrode 24 is provided at the second body array portion 21B disposed adjacently to the first body array portion 21A provided with the array electrode 23.

One end of the hinge array portion 22 is coupled to the first body array portion 21A, and the other end thereof is coupled to the second body array portion 21B. The hinge array portions 22 include a lateral hinge array portion 22A stacked on the lateral hinge 12A and a longitudinal hinge array portion 22B stacked on the longitudinal hinge 12B.

FIG. 5 is a sectional view seen in the direction of arrow along line V-V of FIG. 4. The first body array portion 21A is provided with a transistor 25. The transistor 25 includes a semiconductor layer 25a, a gate insulating film 25b, a gate electrode 25c, a drain electrode 25d, and a source electrode 25e. The drain electrode 25d is coupled to the array electrode 23.

The array electrode 23 and the common electrode 24 are made of conductive material and have a rectangular shape in plan view (refer to FIG. 4). The array electrode 23 and the common electrode 24 are covered by the first resin layer 60 in the first direction X1 and are in contact with the first resin layer 60. Therefore, the array electrode 23 and the common electrode 24 are electrically coupled via the first resin layer 60. Therefore, when a current is supplied to the array electrode 23, it flows to the common electrode 24 via the first resin layer 60 (refer to arrow A in FIG. 5).

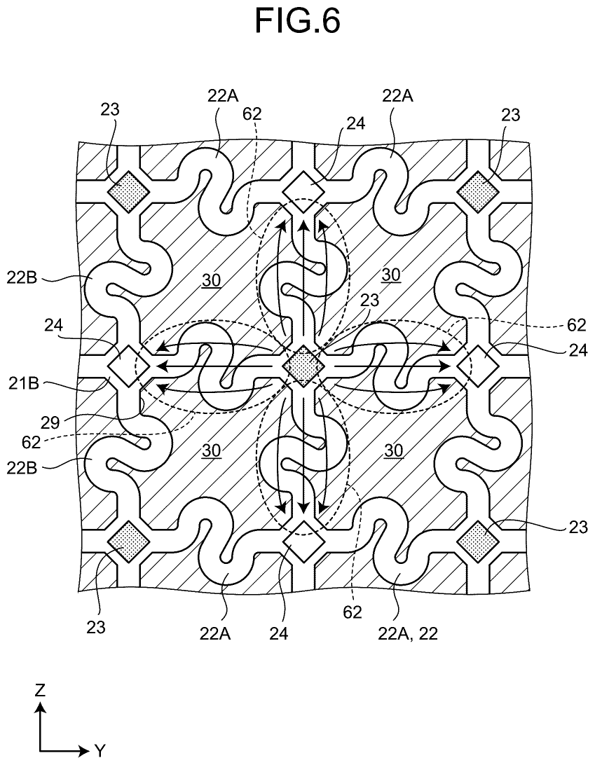

FIG. 6 is a sectional view seen in the direction of arrow along line IV-IV of FIG. 2 and is a schematic of an area in which currents flow. In the following description, a conductive portion 62 refers to a portion of the first resin layer 60 through which a current from the array electrode 23 to the common electrode 24 passes. As illustrated in FIG. 6, the conductive portion 62 is mainly a portion positioned between the array electrode 23 and the common electrode 24 (refer to the area surrounded by the dashed line in FIG. 6) in plan view. In other words, the area overlapping the hinge array portion 22 in plan view is mainly the conductive portion 62. If the resistance of the first resin layer 60 is low, the current flows in an area larger than the area surrounded by the dashed line in FIG. 6. By contrast, if the resistance of the first resin layer 60 is large, the current flows in an area smaller than the area surrounded by the dashed line in FIG. 6. In other words, the conductive portion 62 illustrated in FIG. 6 (the area surrounded by the dashed line in FIG. 6) is an example of the conductive portion according to the present disclosure.

The array layer 20 includes gate lines 31, current supply lines 32, signal lines 33, a coupler 34, a gate line drive circuit 35, a current supply line selection circuit 36, and a signal line selection circuit 37 as components for driving the transistors 25.

As illustrated in FIG. 4, the gate line 31 is provided over a plurality of lateral hinge array portions 22A and a plurality of body array portions 21. As a result, the gate line 31 extends in the first planar direction Y in the detection region 2. The gate line 31 is coupled to the gate electrode 25c of the transistor 25 in the first body array portion 21A (refer to FIG. 5). The end of the gate line 31 in the first planar direction Y extends in the peripheral region 3 and is coupled to the gate line drive circuit 35.

As illustrated in FIG. 4, the current supply line 32 is disposed across a plurality of longitudinal hinge array portions 22B and a plurality of body array portions 21. As a result, the current supply line 32 extends in the second planar direction Z in the detection region 2. The current supply line 32 is coupled to the source electrode 25e in the first body array portion 21A (refer to FIG. 5). The end of the current supply line 32 in the second planar direction Z extends in the peripheral region 3 and is coupled to the current supply line selection circuit 36.

The signal line 33 is disposed across a plurality of longitudinal hinge array portions 22B and a plurality of body array portions 21. As a result, the signal line 33 extends in the second planar direction Z in the detection region 2. The end of the signal line 33 in the second planar direction Z extends in the peripheral region 3 and is coupled to the signal line selection circuit 37. The signal line 33 is coupled to the common electrode 24 in the second body array portion 21B (refer to FIG. 5).

As illustrated in FIG. 1, the coupler 34 is coupled to a drive integrated circuit (IC) disposed outside the stretchable device 1. The drive IC may be mounted as a chip on film (COF) on a flexible printed circuit board or a rigid board, which is not illustrated, and coupled to the coupler 34. Alternatively, the drive IC may be mounted as a chip on glass (COG) in the peripheral region 3 of the first resin layer 60 or the second resin layer 70.

The gate line drive circuit 35 is a circuit that drives a plurality of gate lines 31 (refer to FIG. 4) based on various control signals supplied from the drive IC. The gate line drive circuit 35 sequentially or simultaneously selects the gate lines 31 and supplies gate drive signals to the selected gate lines 31.

The current supply line selection circuit 36 is a switch circuit that sequentially or simultaneously selects a plurality of current supply lines 32. The current supply line selection circuit 36 couples the selected current supply line 32 to the drive IC based on a selection signal supplied from the drive IC. As a result, a predetermined amount of current is supplied from the drive IC to the current supply line 32.

The signal line selection circuit 37 is a switch circuit that sequentially or simultaneously selects a plurality of signal lines 33. The signal line selection circuit 37 couples the selected signal line 33 to the drive IC based on a selection signal supplied from the drive IC. As a result, a current (signal) flowing from the common electrode 24 to the signal line 33 is transmitted to the drive IC.

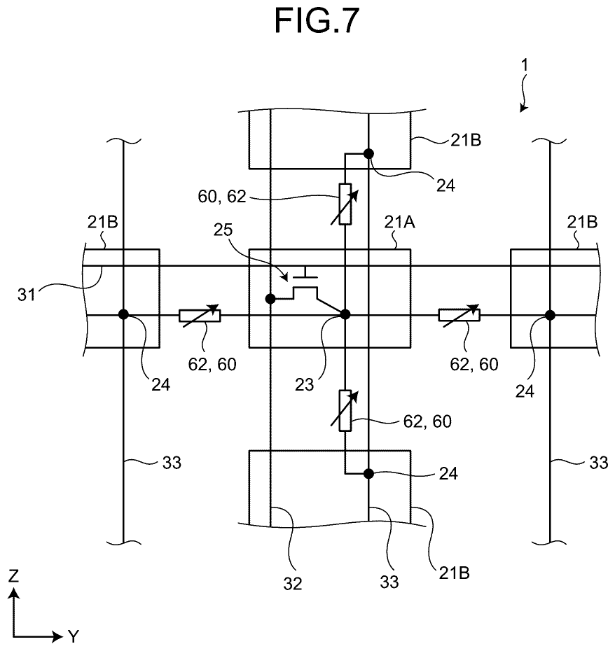

FIG. 7 is a circuit diagram of the circuit configuration of the stretchable device according to a first embodiment. The following describes an example of operations of the stretchable device according to the first embodiment. As illustrated in FIG. 7, when a gate drive signal is transmitted from the gate line 31 to the transistor 25, the transistor 25 is turned ON. The predetermined amount of current supplied from the drive IC flows to the array electrode 23 via the current supply line 32 and the transistor 25. The current flowing through the array electrode 23 flows to the common electrode 24 via the first resin layer 60 (conductive portion 62).

As illustrated in FIG. 6, the common electrodes 24 are respectively disposed on four sides of the array electrode 23, that is, on opposite sides in the first planar direction Y and opposite sides in the second planar direction Z. Therefore, the current flows from the array electrode 23 toward the common electrodes 24 disposed on the four sides. When the signal line 33 coupled to the common electrode 24 is selected by the signal line selection circuit 37, the current flowing through the common electrode 24 returns to the drive IC via the signal line 33.

When a tensile load in the planar direction is applied to the stretchable device 1, the first resin layer 60 (conductive portion 62) is also stretched, and the resistance of the first resin layer 60 (conductive portion 62) increases. As a result, the amount of current flowing from the array electrode 23 to the common electrode 24 decreases. In other words, the amount of current returning to the drive IC is smaller than that when the stretchable device 1 is not deformed.

When a compressive load in the planar direction is applied to the stretchable device 1, the first resin layer 60 (conductive portion 62) is also compressed, and the resistance of the first resin layer 60 (conductive portion 62) decreases. As a result, the amount of current flowing from the array electrode 23 to the common electrode 24 increases. In other words, the amount of current returning to the drive IC is larger than that when the stretchable device 1 is not deformed.

Therefore, the load acting on each part of the stretchable device 1 can be detected by comparing the signal (amount of current) received by the drive IC with the signal (amount of current) received when the stretchable device 1 is not deformed. The hinge array portions 22 according to the present embodiment are not provided with strain gauges. This configuration prevents compromising the stretchability and flexibility of the stretchable device 1.

While the first embodiment has been described above, the present disclosure is not limited to the example described in the first embodiment. While the entire first resin layer 60 is made of conductive resin, for example, only the part corresponding to the conductive portion 62 may be made of conductive resin, and the part other than the conductive portion 62 may be made of insulating resin.

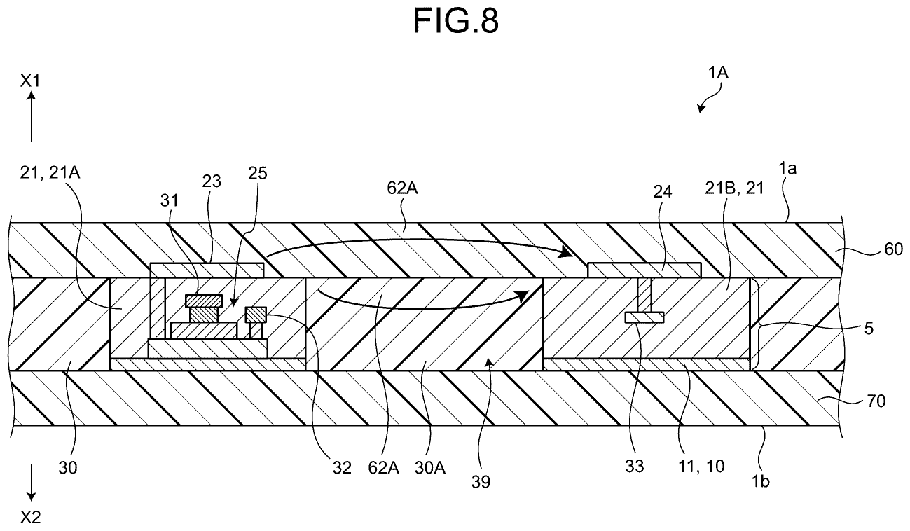

FIG. 8 is a sectional view of the stretchable device according to a first modification. In the stretchable device according to the present disclosure, an intermediate resin portion 30A provided in the hollow hole 39 may be made of conductive resin as illustrated in FIG. 8. With this configuration, the current flows not only through the first resin layer 60 but also through the intermediate resin portion 30A. In other words, in a stretchable device 1A according to the first modification, not only the first resin layer 60 but also part of the intermediate resin portion 30A serves as a conductive portion 62A.

While the array electrode 23 and the common electrode 24 according to the first embodiment are in contact with the first resin layer 60, the array electrode 23 and the common electrode 24 according to the present disclosure are not necessarily in contact with the first resin layer 60. The following describes a second embodiment in which the array electrode 23 and the common electrode 24 are not in contact with the first resin layer 60. The following mainly describes the differences from the first embodiment.

### Second Embodiment

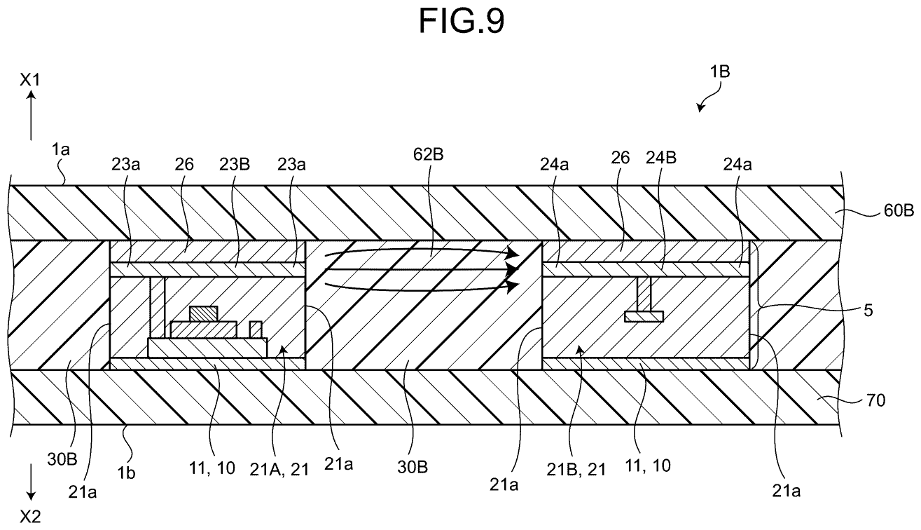

FIG. 9 is a sectional view of the stretchable device according to the second embodiment. As illustrated in FIG. 9, a stretchable device 1B according to the second embodiment is different from the first embodiment in that an insulating layer 26 is provided on an array electrode 23B and a common electrode 24B of the array substrate 5 in the first direction X1. The second embodiment is different from the first embodiment in that part of the array electrode 23B and the common electrode 24B is in contact with an intermediate resin portion 30B. The second embodiment is different from the first embodiment in that the intermediate resin portion 30B is made of conductive resin. The second embodiment is different from the first embodiment in that a first resin layer 60B has insulating properties. The following describes the differences.

The insulating layer 26 covers the entire surface of the array electrode 23B and the common electrode 24B in the first direction X1. Therefore, the array electrode 23B and the common electrode 24B are not in contact with the first resin layer 60B. Part of the array electrode 23B and part of the common electrode 24B are exposed from side surfaces 21a of the body array portion 21 and are in contact with the intermediate resin portion 30B. In the following description, the parts of the array electrode 23B and the common electrode 24B in contact with the intermediate resin portion 30B are referred to as coupling portions 23a and 24a.

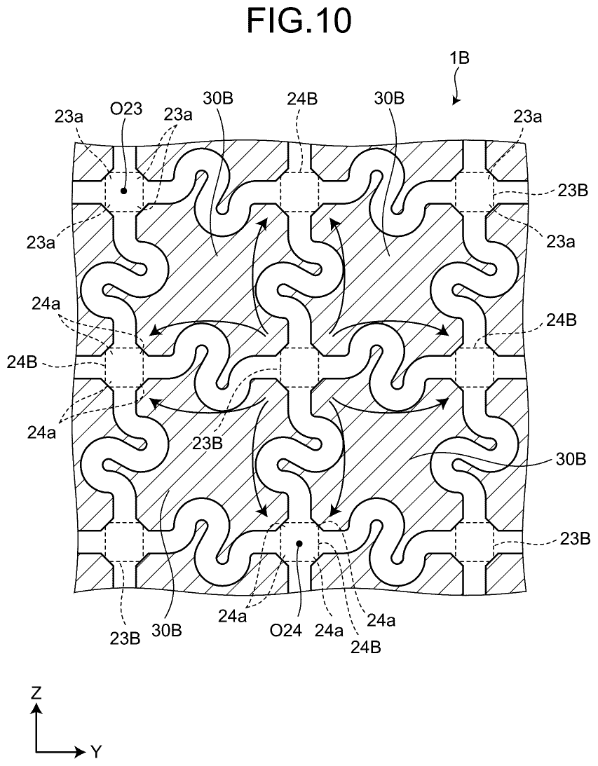

FIG. 10 is a plan view of the array substrate of the stretchable device according to the second embodiment viewed from the first resin layer. The coupling portion 23a is positioned in an oblique direction shifted by 45 degrees with respect to the first planar direction Y or the second planar direction Z when viewed from the center O23 of the array electrode 23B. Therefore, one array electrode 23B is provided with four coupling portions 23a. Similarly, the coupling portion 24a is positioned in an oblique direction shifted by 45 degrees with respect to the first planar direction Y or the second planar direction Z when viewed from the center O24 of the common electrode 24B. Therefore, one common electrode 24B is provided with four coupling portions 23a. As a result, the array electrode 23B and the common electrode 24B are in contact with four intermediate resin portions 30B disposed around the body array portion 21.

As described above, the array electrode 23B and the common electrode 24B according to the second embodiment are electrically coupled by the intermediate resin portion 30B (refer to the arrows in FIG. 9). In other words, part of the intermediate resin portion 30B according to the second embodiment serves as a conductive portion 62B. As illustrated in FIG. 10, the current flows in a manner bypassing the hinge array portion 22 as indicated by the arrows in FIG. 10. In other words, the current flows through the part of the intermediate resin portion 30B adjacent to the hinge array portion 22 in plan view. Therefore, the area of the intermediate resin portion 30B overlapping the arrows in FIG. 10 serves as the conductive portion 62B. When a load in the planar direction acts on the stretchable device 1B, the intermediate resin portion 30B (conductive portion 62B) is deformed in the same manner as the array substrate 5, and the resistance changes. Therefore, the second embodiment can also detect the load acting on each part.

The stretchable device according to the present disclosure may be the stretchable device 1B in which the first resin layer 60B according to the second embodiment is made of conductive resin. The array electrode according to the present disclosure may be the array electrode 23 described in the first embodiment, and the common electrode according to the present disclosure may be the common electrode 24B described in the second embodiment. Alternatively, the array electrode according to the present disclosure may be the array electrode 23B described in the second embodiment, and the common electrode according to the present disclosure may be the common electrode 24 described in the first embodiment. In other words, the positions of the array electrode 23 and the common electrode 24 are not limited to those described in the first and the second embodiments.

The following describes a stretchable device 1C according to a third embodiment obtained by modifying part of the stretchable device 1B according to the second embodiment.

### Third Embodiment

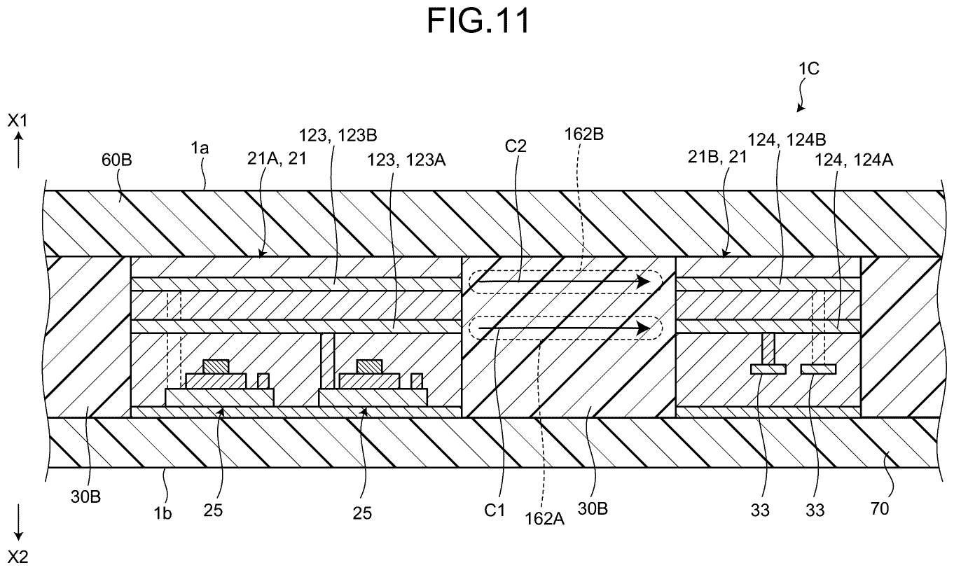

FIG. 11 is a sectional view of the stretchable device according to the third embodiment. As illustrated in FIG. 11, the stretchable device 1C according to the third embodiment is different from the second embodiment in that one first body array portion 21A is provided with two transistors 25. The third embodiment is different from the second embodiment in that the first body array portion 21A is provided with two array electrodes 123. The third embodiment is different from the second embodiment in that one second body array portion 21B is provided with two common electrodes 124. The following describes the differences.

The two array electrodes 123 are disposed apart from each other in the stacking direction. In the following description, the array electrode 123 disposed closer to the transistor 25 (disposed in the second direction X2) out of the two array electrodes 123 is referred to as a first array electrode 123A. The array electrode 123 disposed away from the transistor 25 in the stacking direction is referred to as a second array electrode 123B.

Similarly, the two common electrodes 124 are disposed apart from each other in the stacking direction. In the following description, one of the two common electrodes 124 disposed closer to the resin base member 10 is referred to as a first common electrode 124A. The other thereof disposed away from the resin base member 10 in the stacking direction is referred to as a second common electrode 124B.

With respect to the positional relation in the stacking direction, the first array electrode 123A and the first common electrode 124A are at the same height, and the second array electrode 123B and the second common electrode 124B are at the same height. Therefore, when a current is supplied to the first array electrode 123A, it flows to the first common electrode 124A via the intermediate resin portion 30B (refer to arrow C1). When a current is supplied to the second array electrode 123B, it flows to the second common electrode 124B via the intermediate resin portion 30B (refer to arrow C2). Thus, the two array electrodes 123 and the two common electrodes 124 are each separated in the stacking direction such that the first array electrode 123A is electrically coupled to the first common electrode 124A and that the second array electrode 123B is electrically coupled to the second common electrode 124B. In the following description, the part of the intermediate resin portion 30B between the first array electrode 123A and the first common electrode 124A is referred to as a first conductive portion 162A. The part between the second array electrode 123B and the second common electrode 124B is referred to as a second conductive portion 162B.

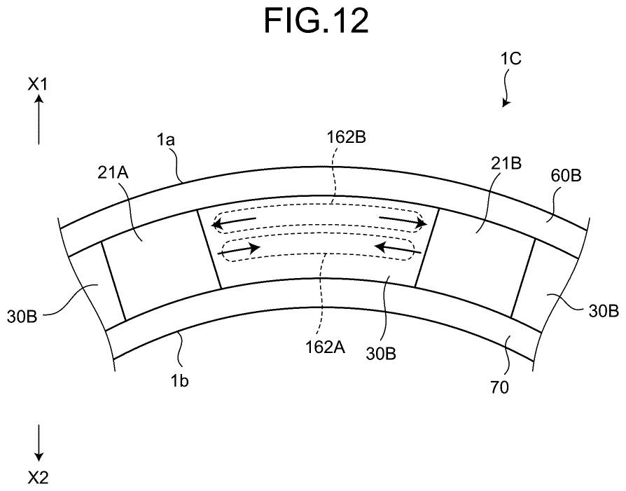

FIG. 12 is a schematic of the stretchable device according to the third embodiment on which a bending load acts, as viewed in the planar direction. When a bending load acts on the stretchable device 1C, the stretchable device 1C bends. As a result, the intermediate resin portion 30B also bends. As illustrated in FIG. 12, the second conductive portion 162B is disposed in the first direction X1 with respect to the first conductive portion 162A. Therefore, the amounts of deformation (amounts of bending) acting on the first conductive portion 162A and the second conductive portion 162B are different, or the directions of the load (compressive load or tensile load) acting on the first conductive portion 162A and the second conductive portion 162B are different. In FIG. 12, a compressive load acts on the first conductive portion 162A, and a tensile load acts on the second conductive portion 162B.

When the stretchable device 1C bends, the amount of current flowing from the first array electrode 123A to the first common electrode 124A is different from the amount of current flowing from the second array electrode 123B to the second common electrode 124B. Therefore, the bending load acting on each part of the stretchable device 1C can be detected. When the load acting on the stretchable device 1C is a load in the planar direction, the amount of current flowing from the first array electrode 123A to the first common electrode 124A is equal to the amount of current flowing from the second array electrode 123B to the second common electrode 124B. Therefore, the third embodiment can also detect the load in the planar direction (tensile load and compressive load).

The following describes a stretchable device 1D according to a fourth embodiment obtained by modifying part of the stretchable device 1 according to the first embodiment.

### Fourth Embodiment

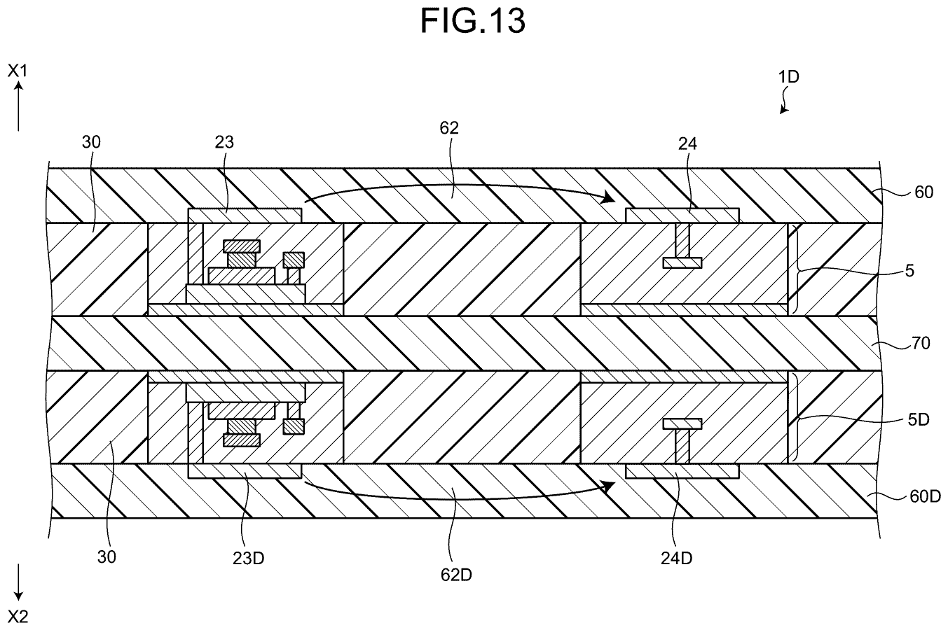

FIG. 13 is a sectional view of the stretchable device according to the fourth embodiment. As illustrated in FIG. 13, the stretchable device 1D according to the fourth embodiment is different from the first embodiment in that it further includes an array substrate 5D and a first resin layer 60D on the second resin layer 70 in the second direction X2. The stretchable device 1D according to the fourth embodiment can detect strain (deformation) generated in the first direction X1 with respect to the second resin layer 70 using the array substrate 5 and the first resin layer 60. The stretchable device 1D can also detect strain (deformation) generated in the second direction X2 with respect to the second resin layer 70 using the array substrate 5D and the first resin layer 60D.

As described above, the stretchable device 1D according to the fourth embodiment includes two array substrates 5 and 5D stacked in the stacking direction. The bending load acting on the stretchable device 1D can be detected by the two array substrates 5 and 5D.

While the common electrode 24 is provided at the second body array portion 21B in the description of the first to the fourth embodiments, the common electrode 24 according to the present disclosure may be provided at a position other than the second body array portion 21B. More specifically, the common electrode 24 simply needs to be provided at a position other than the first body array portion 21A provided with the array electrode 23. If the array electrode 23 and the common electrode 24 are disposed on the same first body array portion 21A, the array electrode 23 and the common electrode 24 are electrically coupled by the part of the first resin layer 60 stacked on the first body array portion 21A (conductive portion 62). However, when a load is applied to the stretchable device 1, the conductive portion 62 stacked on the first body array portion 21A is hard to deform. Therefore, the resistance of the conductive portion 62 does not change, and strain fails to be detected. For this reason, the common electrode 24 needs to be disposed at a position other than the first body array portion 21A provided with the array electrode 23.

The following describes a stretchable device 1E according to a fifth embodiment in which the common electrode 24 is provided at a position other than the second body array portion 21B.

### Fifth Embodiment

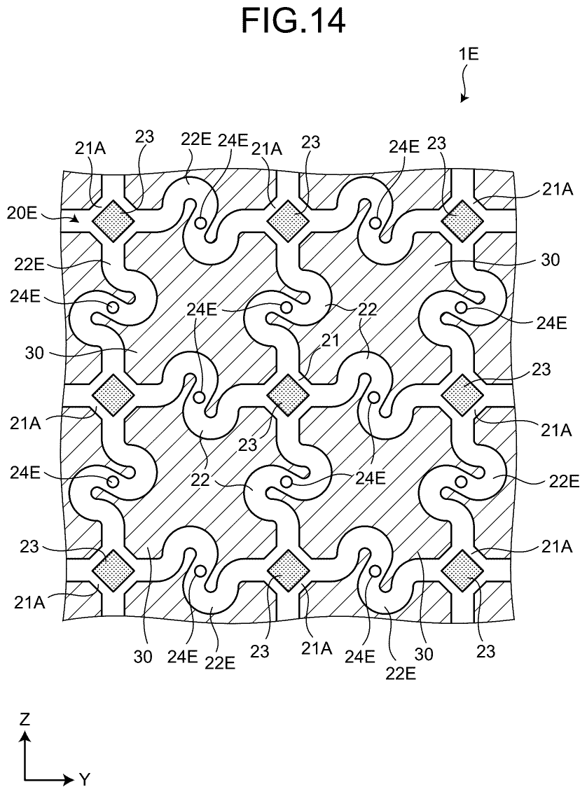

FIG. 14 is a plan view of the array substrate of the stretchable device according to the fifth embodiment viewed from the first resin layer. As illustrated in FIG. 14, the stretchable device 1E according to the fifth embodiment is different from the first embodiment in that all the body array portions 21 are the first body array portions 21A. Therefore, the array electrodes 23 according to the fifth embodiment are arrayed in a grid-like manner in the first planar direction Y and the second planar direction Z. In other words, an array layer 20E according to the fifth embodiment does not include the second body array portion 21B (refer to FIGS. 4 and 5) provided with the common electrode 24.

A hinge array portion 22E according to the fifth embodiment is different from the first embodiment in that it is provided with a common electrode 24E. The common electrode 24E has a circular shape in plan view. The common electrode 24E is provided on the surface of the hinge array portion 22E in the first direction X1 and is in contact with the first resin layer 60. Therefore, the array electrode 23 and the common electrode 24E are electrically coupled by the first resin layer 60. The common electrode 24E is disposed at the center of the hinge array portion 22E in the length direction. Therefore, the distances from the common electrode 24E to two array electrodes 23 disposed on opposite sides in the first planar direction Y or the second planar direction Z are equal.

As described above, in the stretchable device 1E according to the fifth embodiment, the distance between the array electrode 23 and the common electrode 24E is shorter than that according to the first embodiment. In other words, the area for detecting strain is smaller, and the resolution of the area for detecting force is improved.

While the fifth embodiment has been described above, part of the common electrode 24E according to the present disclosure may be exposed from the side surfaces of the hinge array portion 22E and be in contact with the conductive resin (intermediate resin portion 30B). In this case, part of the array electrode 23 may be exposed from the side surfaces 21a of the first body array portion 21A and be in contact with the conductive resin (intermediate resin portion 30B) as described in the second embodiment.

While the embodiments and the modifications have been described above, the circuit configuration according to the present disclosure is not limited to the example illustrated in FIG. 7. The following describes a second modification obtained by modifying the circuit configuration.

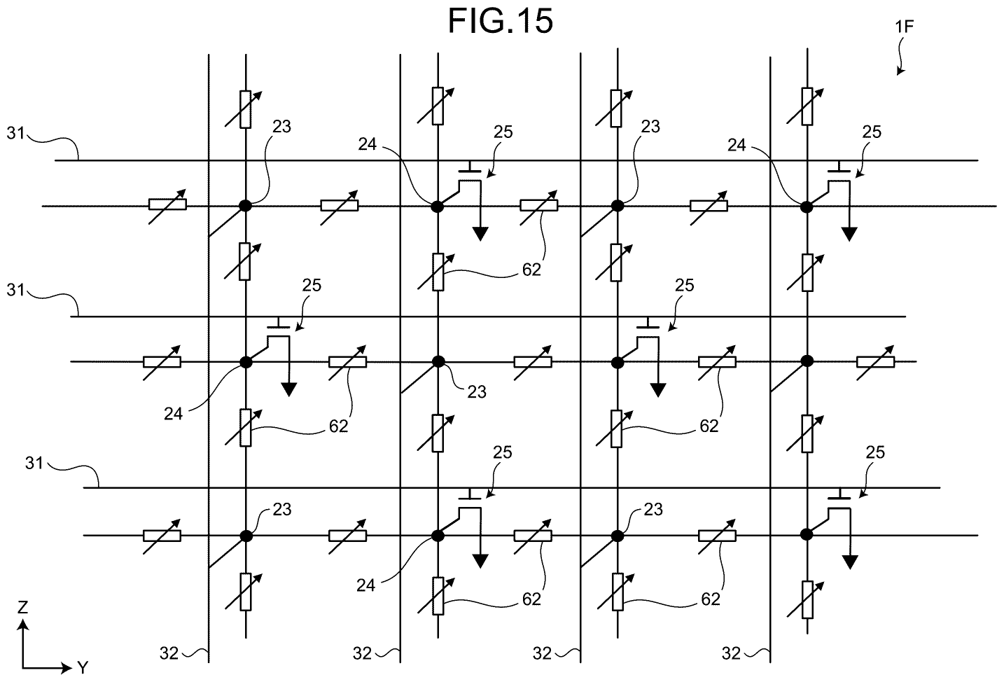

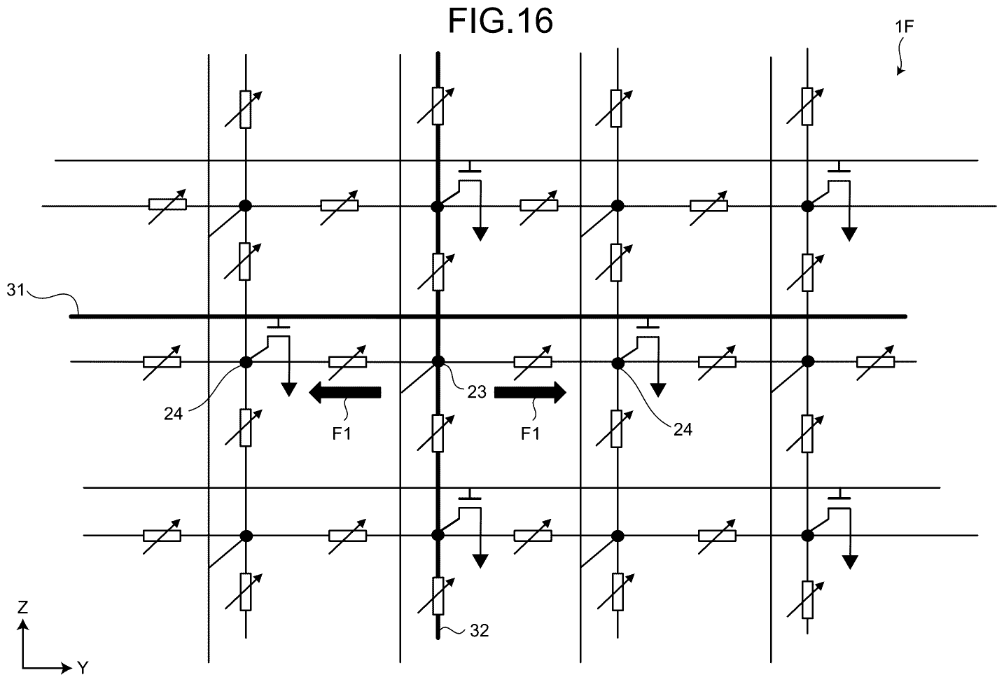

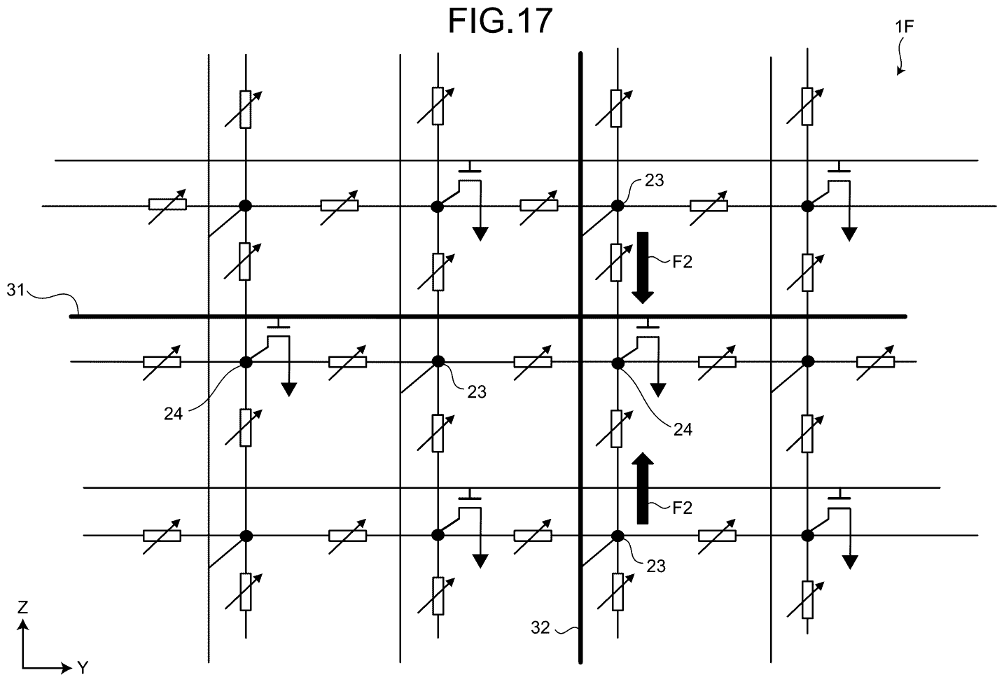

FIG. 15 is a circuit diagram of the circuit configuration according to the second modification. FIG. 16 is a schematic of an example of the state in detection in the second modification. FIG. 17 is a schematic of an example of the state in detection in the second modification. As illustrated in FIG. 15, a stretchable device 1F according to the second modification is the same as the first embodiment in that it includes a plurality of gate lines 31 and a plurality of current supply lines 32. By contrast, the stretchable device 1F according to the second modification is different from the first embodiment in that it does not include a plurality of signal lines 33. Therefore, the stretchable device 1F does not include the signal line selection circuit 37 (refer to FIG. 1).

The gate electrode of the transistor 25 is coupled to the gate line 31. The drain electrode of the transistor 25 is coupled to the common electrode 24. The source electrode of the transistor 25 is coupled to a ground. When the gate drive signal is transmitted to the transistor 25, the transistor 25 is turned ON, and the potential of the common electrode 24 is 0 V. The current supply line 32 is coupled to the array electrode 23. With the circuit configuration according to the second modification, when the gate drive signal is input to the gate line 31, and the drive IC then applies a voltage to the current supply line 32, a current flows to the common electrode 24 via the current supply line 32 and the conductive portion 62.

Specifically, as illustrated in FIG. 16, if the electrode positioned at the intersection of the gate line 31 supplied with the gate drive signal and the current supply line 32 supplied with the voltage is the array electrode 23, the current flows from the array electrode 23 to the common electrodes 24 positioned on opposite sides of the array electrode 23 in the first planar direction Y (refer to arrows F1 in FIG. 16).

As illustrated in FIG. 17, if the electrode positioned at the intersection of the gate line 31 supplied with the gate drive signal and the current supply line 32 supplied with the voltage is the common electrode 24, the current flows from the array electrodes 23 positioned on opposite sides of the common electrode 24 in the second planar direction Z to the common electrode 24 (refer to arrows F2 in FIG. 17).

In the circuit configuration according to the second modification, the drive IC sets the voltage applied to the current supply line 32 to a constant value (constant voltage value). With this configuration, when the resistance of the conductive portion 62 changes, the amount of current flowing to the common electrode 24 changes. In other words, when a tensile load and a compressive load act on the stretchable device 1F, the amount of current flowing from the drive IC to the current supply line 32 also changes. Therefore, the drive IC can detect the load acting on the conductive portion 62 by detecting the amount of current flowing from the drive IC to the current supply line 32.

While the circuit configuration according to the second modification has been described above, the present disclosure may have another circuit configuration and is not particularly limited. In the present disclosure, all the first resin layer 60, the intermediate resin portion 30, and the second resin layer 70 may be made of conductive resin.

What is claimed is:

1. A stretchable device comprising:
an array substrate comprising a resin base member and an array layer stacked on the resin base member, wherein
the resin base member comprises:
a plurality of bodies disposed apart from one another; and
a plurality of hinges that couple the bodies,
the array layer comprises:
a plurality of body array portions provided at the bodies; and
a plurality of hinge array portions provided at the hinges,
a first body array portion serving as at least part of the body array portions is provided with an array electrode,
a common electrode is provided at part of the array layer other than the first body array portion, and
a conductive portion made of conductive resin is provided between the array electrode and the common electrode, the conductive portion being configured to electrically couple the array electrode to the common electrode and including a conductive filler inside.

2. The stretchable device according to claim 1, wherein
a direction in which the array layer is disposed when viewed from the resin base member is a first direction,
a first resin layer stacked on the array layer in the first direction is provided,
the array electrode and the common electrode are in contact with the first resin layer, and
the first resin layer is the conductive portion.

3. The stretchable device according to claim 1, wherein
the array layer has a plurality of array layer through-holes surrounded by the body array portions and the hinge array portions and passing through the array layer,
an intermediate resin portion is provided in the array layer through-holes,
the array electrode and the common electrode are in contact with the intermediate resin portion, and
the intermediate resin portion is the conductive portion.

4. The stretchable device according to claim 1, wherein
a direction in which the array layer is disposed when viewed from the resin base member is a first direction,
a first resin layer stacked on the array layer in the first direction is provided,
the array layer has a plurality of first through-holes surrounded by the body array portions and the hinge array portions and passing through the array layer,
an intermediate resin portion is provided in the first through-holes,
the array electrode and the common electrode are in contact with the first resin layer or the intermediate resin portion, and
the first resin layer and the intermediate resin portion are the conductive portion.

5. The stretchable device according to claim 1, wherein the common electrode is provided at a second body array portion disposed adjacently to the first body array portion.

6. The stretchable device according to claim 1, wherein the common electrode is provided at the hinge array portion coupled to the first body array portion.

7. The stretchable device according to claim 1, wherein
the first body array portion is provided with a first array electrode and a second array electrode serving as two of the array electrodes,
a first common electrode and a second common electrode serving as two of the common electrodes are provided, and
the two array electrodes and the two common electrodes are each separated in a stacking direction of the resin base member and the array layer such that the first array electrode is electrically coupled to the first common electrode and that the second array electrode is electrically coupled to the second common electrode.

8. The stretchable device according to claim 5, wherein
the first body array portion is provided with a first array electrode and a second array electrode serving as two of the array electrodes,
a first common electrode and a second common electrode serving as two of the common electrodes are provided, and
the two array electrodes and the two common electrodes are each separated in a stacking direction of the resin base member and the array layer such that the first array electrode is electrically coupled to the first common electrode and that the second array electrode is electrically coupled to the second common electrode.

9. The stretchable device according to claim 6, wherein
the first body array portion is provided with a first array electrode and a second array electrode serving as two of the array electrodes,
a first common electrode and a second common electrode serving as two of the common electrodes are provided, and
the two array electrodes and the two common electrodes are each separated in a stacking direction of the resin base member and the array layer such that the first array electrode is electrically coupled to the first common electrode and that the second array electrode is electrically coupled to the second common electrode.

10. The stretchable device according to claim 1, wherein
two of the array substrates are provided, and
the two array substrates are stacked in a stacking direction of the resin base member and the array layer.

11. The stretchable device according to claim 5, wherein
two of the array substrates are provided, and
the two array substrates are stacked in a stacking direction of the resin base member and the array layer.

12. The stretchable device according to claim 6, wherein
two of the array substrates are provided, and
the two array substrates are stacked in a stacking direction of the resin base member and the array layer.
